(19) United States
(12) Patent Application Publication
(10) Pub. No.: US 2013/0266771 A1
(43) Pub. Date: Oct. 10, 2013

(54) DISPLAY PANEL WITH CURVED SHAPE AND RADIUS ACQUISION METHOD FOR THE SAME

(71) Applicants: Susumu KUSANO, Saitama (JP); Yoshinori Onoue, Tokyo (JP); Keiji Naoi, Tokyo (JP); Moonik Jang, Seoul (KR)

(72) Inventors: Susumu KUSANO, Saitama (JP); Yoshinori Onoue, Tokyo (JP); Keiji Naoi, Tokyo (JP); Moonik Jang, Seoul (KR)

(21) Appl. No.: 13/773,724

(22) Filed: Feb. 22, 2013

(30) Foreign Application Priority Data
Apr. 6, 2012 (KR) 10-2012-0036342

(51) Int. Cl. H05K 7/00

(52) U.S. Cl. CPC H05K 7/00
USPC 428/174; 29/592

(57) ABSTRACT

Disclosed is a curved display panel having a predetermined radius of curvature based on a horizontal width of the display panel and a viewing coefficient based on the horizontal width and the radius of curvature has a positive value, wherein the viewing coefficient is a value based on a viewing angle of the display panel in a flat state and a viewing angle of the display panel in a curved state.

### CROSS-REFERENCE TO RELATED APPLICATION

Pursuant to 35 U.S.C. §119(a), this application claims the benefit of earlier filing date and right of priority to Korean Application No. 10-2012-0036342, filed on Apr. 6, 2012, the contents of which is incorporated by reference herein in its entirety.

### BACKGROUND OF THE INVENTION

1. Field of the Invention

The present disclosure relates to a curved display panel and a method for acquiring a radius of curvature of a curved display panel.

2. Background of the Invention

A conventional general display panel has a viewing plane in a flat form. However, as the technology has been developed, recently, a curved display panel having a bent viewing plane has been produced and used.

However, an effect obtained when the curved display panel is used has not been properly conducted.

Thus, a method for providing high quality presence characteristics by using a curved display panel and a method for reducing an influence of viewing angle characteristics relying on a display panel and improving uniformity of a display screen are required to be discussed.

### SUMMARY OF THE INVENTION

Therefore, the present disclosure provides methods for solving the foregoing problems.

In detail, an aspect of the detailed description is to provide a curved display panel providing an image having high quality presence characteristics by a wide view viewing angle.

Another aspect of the detailed description is to provide a curved display panel which is less affected by viewing angle characteristics relying on a display panel and having improved uniformity of a display screen.

To achieve these and other advantages and in accordance with the purpose of this specification, as embodied and broadly described herein, A display device comprises a body and a curved display panel mounted at the body, wherein a curved display panel has a predetermined radius of curvature based on a horizontal width of the display panel and a viewing coefficient based on the horizontal width and the radius of curvature has a positive value, wherein the viewing coefficient is a value based on a viewing angle of the display panel in a flat state and a viewing angle of the display panel in a curved state.

In the display device according to another aspect of the present invention, the viewing angle of the display panel in a curved state is expressed by Equation 1 shown below, and the viewing angle of the display panel in the flat state is expressed by Equation 2 shown below.

$$\begin{matrix}φ Wc = {tan}^{- 1} ( \frac{L \times sin ( X ) + \frac{Wc}{2}}{L \times cos ( X ) - Δ D} ) - {tan}^{- 1} ( \frac{L \times sin ( X ) + \frac{Wc}{2}}{L \times cos ( X ) - Δ D} ) & ( Equation 1 ) \\ φ Wf = {tan}^{- 1} ( \frac{L \times sin ( X ) + \frac{W}{2}}{L \times cos ( X )} ) - {tan}^{- 1} ( \frac{L \times sin ( X ) - \frac{W}{2}}{L \times cos ( X )} ) & ( Equation 2 )\end{matrix}$$

Here, L is a view distance, X is a view angle, ΔD is a length between the front and the rear of the display plane before and after the display plane is curved, W is a horizontal width of the display panel before the display panel is curved, and Wc is a horizontal width of the display panel after the display panel is curved.

In the display device according to another aspect of the present invention, the viewing coefficient is expressed by Equation 3 shown below.

φWc−φWf (Equation 3)

In the display device according to another aspect of the present invention, the view angle (X) has a value ranging from 30° to 60°.

In the display device according to another aspect of the present invention, the predetermined radius of curvature is a radius of curvature based on at least one of viewing coefficients with respect to a plurality of sets including a plurality of curvatures information.

In the display device according to another aspect of the present invention, a panel viewing coefficient based on the horizontal width and the radius of curvature has a positive value, and the panel viewing coefficient is a value based on a panel viewing angle of the display panel in a flat state and a panel viewing angle of the display panel in a curved state.

In the display device according to another aspect of the present invention, the panel viewing angle of the display panel in a flat state is expressed by Equation 4 shown below, and the panel viewing angle of the display panel in a curved state is expressed by Equation 5 shown below.

$$\begin{matrix}φ Xf = {tan}^{- 1} ( \frac{L \times sin ( X ) + \frac{W}{2}}{L \times cos ( X )} ) & ( Equation 4 ) \\ φ Xc = {tan}^{- 1} ( \frac{L \times sin ( X ) - \frac{Wc}{2}}{L \times cos ( X ) - Δ D} ) + φ c & ( Equation 5 )\end{matrix}$$

Here, L is a view distance, X is a view angle, ΔD is a length between the front and the rear of the display plane before and after the display panel is curved, W is a horizontal width of the display panel before the display panel is curved, Wc is a horizontal width of the display panel after the display panel is curved, and φc is a curvature angle.

In the display device according to another aspect of the present invention, the panel viewing coefficient is expressed by Equation 6 shown below.

φWf−φWc (Equation 6)

In the display device according to another aspect of the present invention, the predetermined radius of curvature is a radius of curvature based on at least one of panel viewing coefficients with respect to a plurality of sets including a plurality of curvatures information.

In the display device according to another aspect of the present invention, the radius of curvature has a value equal to or greater than a minimum radius of curvature, and the minimum radius of curvature is expressed by Equation 7 shown below.

Rcmin′(mm)=0.10927×W(mm)+3545 (mm) (Equation 7)

Here, Rcmin′ is a minimum radius of curvature, and W is a horizontal width of the display panel before the display panel is curved.

In the display device according to another aspect of the present invention, the display panel is curved in a horizontal direction.

In the display device according to another aspect of the present invention, the view distance (L) is 3,000 mm, and the view angle (X) is +60° or −60°.

In the display device according to another aspect of the present invention, the view distance (L) is 5,000 mm, and the view angle (X) is +45° or −45°.

In the display device according to another aspect of the present invention, the view distance (L) is 6,000 mm, and the view angle (X) is +30° or −30°.

To achieve these and other advantages and in accordance with the purpose of this specification, as embodied and broadly described herein, a method for acquiring a radius of curvature of a curved display panel may include: obtaining a viewing coefficient based on a viewing angle of the display panel in a flat state and a viewing angle of the display panel in a curved state, at a predetermined spot; and acquiring a radius of curvature based on the acquired viewing coefficient.

The method for acquiring a radius of curvature according to another aspect of the present invention further includes: acquiring a difference between the viewing angle of the display panel in a curved state and the viewing angle of the display panel in a flat state, wherein the viewing angle of the display panel in a curved state is expressed by Equation 8 shown below and the viewing angle of the display panel in a flat state is expressed by Equation 9 shown below.

$$\begin{matrix}φ Wc = {tan}^{- 1} ( \frac{L \times sin ( X ) + \frac{Wc}{2}}{L \times cos ( X ) - Δ D} ) - {tan}^{- 1} ( \frac{L \times sin ( X ) - \frac{Wc}{2}}{L \times cos ( X ) - Δ D} ) & ( Equation 8 ) \\ φ Wf = {tan}^{- 1} ( \frac{L \times sin ( X ) + \frac{W}{2}}{L \times cos ( X )} ) - {tan}^{- 1} ( \frac{L \times sin ( X ) - \frac{W}{2}}{L \times cos ( X )} ) & ( Equation 9 )\end{matrix}$$

Here, L is a view distance, X is a view angle, ΔD is a length between the front and the rear of the display plane before and after the display panel is curved, W is a horizontal width of the display panel before the display panel is curved, and Wc is a horizontal width of the display panel after the display panel is curved.

The method for acquiring a radius of curvature according to another aspect of the present invention may further include: obtaining a panel viewing coefficient based on a panel viewing angle of the display panel in a flat state and a panel viewing angle of the display panel in a curved state, at a predetermined spot; and acquiring a radius of curvature based on the acquired panel viewing coefficient.

In the method for acquiring a radius of curvature according to another aspect of the present invention, the acquiring of the panel viewing coefficient further includes: acquiring a difference between the panel viewing angle of the display panel in a flat state and the panel viewing angle of the display panel in a curved state, wherein the panel viewing angle of the display panel in a flat state is expressed by Equation 10 shown below and the panel viewing angle of the display panel in a curved state is expressed by Equation 11 shown below.

$$\begin{matrix}φ Xf = {tan}^{- 1} ( \frac{L \times sin ( X ) + \frac{W}{2}}{L \times cos ( X )} ) & ( Equation 10 ) \\ φ Xc = {tan}^{- 1} ( \frac{L \times sin ( X ) - \frac{Wc}{2}}{L \times cos ( X ) - Δ D} ) + φ c & ( Equation 11 )\end{matrix}$$

Here, L is a view distance, X is a view angle, ΔD is a length between the front and the rear of the display plane before and after the display panel is curved, W is a horizontal width of the display panel before the display panel is curved, Wc is a horizontal width of the display panel after the display panel is curved, and φc is a curvature angle.

In the method for acquiring a radius of curvature according to another aspect of the present invention, the acquiring of the viewing coefficient further includes: acquiring a plurality of viewing coefficients with respect to sets including a plurality of curvature information; and selecting at least one of the plurality of acquired viewing coefficients.

In the method for acquiring a radius of curvature according to another aspect of the present invention, the radius of curvature has a value equal to or greater than a minimum radius of curvature, and the minimum radius of curvature is expressed by Equation 12 shown below.

Rcmin′(mm)=0.10927×W(mm)+3545 (mm) (Equation 12)

Here, Rcmin′ is a minimum radius of curvature, and W is a horizontal width of the display panel before the display panel is curved.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the detailed description.

### BRIEF DESCRIPTION OF THE DRAWINGS

The accompanying drawings, which are included to provide a further understanding of the invention and are incorporated in and constitute a part of this specification, illustrate exemplary embodiments and together with the description serve to explain the principles of the invention.

In the drawings:

FIG. 1 illustrates a conceptual view showing a display plane of a display panel curved in a horizontal direction by a predetermined radius of curvature;

FIG. 2 illustrates a conceptual view showing information required for determining radius of curvature of curved display;

FIG. 3 illustrates a view showing a viewing angle when a viewer views a curved display panel at an arbitrary spot;

FIG. 4 illustrates a view showing viewing coefficients with respect to radius of curvature in predetermined view spots with respect to 42-inch, 47-inch, 55-inch, and 60-inch display panels having an aspect ratio of 16:9;

FIG. 5 illustrates a view showing viewing coefficients with respect to radius of curvature in predetermined view spots with respect to 42-inch, 47-inch, 55-inch, and 60-inch display panels having an aspect ratio of 16:9;

FIG. 6 illustrates a view showing a panel viewing angle when a viewer views the curved display panel in an arbitrary spot;

FIG. 7 illustrates a view showing actual view position situation data with respect to a television receiver reported by Japan Ergonomics Society;

FIG. 8 illustrates a view showing a maximum value of a panel viewing angle according to radius of curvature according to predetermined conditions with respect to a display having a predetermined horizontal width;

FIG. 9 illustrates a view showing a maximum value of a panel viewing angle according to radius of curvature according to predetermined conditions with respect to a display having a predetermined horizontal width;

FIG. 10 illustrates a view showing a maximum value of a panel viewing angle according to radius of curvature according to predetermined conditions with respect to a display having a predetermined horizontal width;

FIG. 11 illustrates a graph showing correlation between a horizontal width of a display plane and a minimum radius of curvature for improving uniformity of the display plane before a panel is curved; and

FIG. 12 illustrates an approximated graph showing correlation between a horizontal width of a display plane and a minimum radius of curvature for improving uniformity of the display plane before a panel is curved.

### DETAILED DESCRIPTION OF THE INVENTION

Description will now be given in detail of the exemplary embodiments, with reference to the accompanying drawings. For the sake of brief description with reference to the drawings, the same or equivalent components will be provided with the same reference numbers, and description thereof will not be repeated.

Technical terms used in this specification are used to merely illustrate specific embodiments, and should be understood that they are not intended to limit the present disclosure. As far as not being defined differently, all terms used herein including technical or scientific terms may have the same meaning as those generally understood by an ordinary person skilled in the art to which the present disclosure belongs to, and should not be construed in an excessively comprehensive meaning or an excessively restricted meaning. In addition, if a technical term used in the description of the present disclosure is an erroneous term that fails to clearly express the idea of the present disclosure, it should be replaced by a technical term that can be properly understood by the skilled person in the art. In addition, general terms used in the description of the present disclosure should be construed according to definitions in dictionaries or according to its front or rear context, and should not be construed to have an excessively restrained meaning.

As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, steps, operations, elements, components, and/or groups thereof.

Suffixes “module” and “unit or portion” for components used herein in description are merely provided only for facilitation of preparing this specification, and thus they are not granted a specific meaning or function.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

The embodiments of the present invention will now be described with reference to the accompanying drawings, in which like numbers refer to like elements throughout.

In describing the present invention, if a detailed explanation for a related known function or construction is considered to unnecessarily divert the gist of the present invention, such explanation has been omitted but would be understood by those skilled in the art. The accompanying drawings of the present invention aim to facilitate understanding of the present invention and should not be construed as limited to the accompanying drawings.

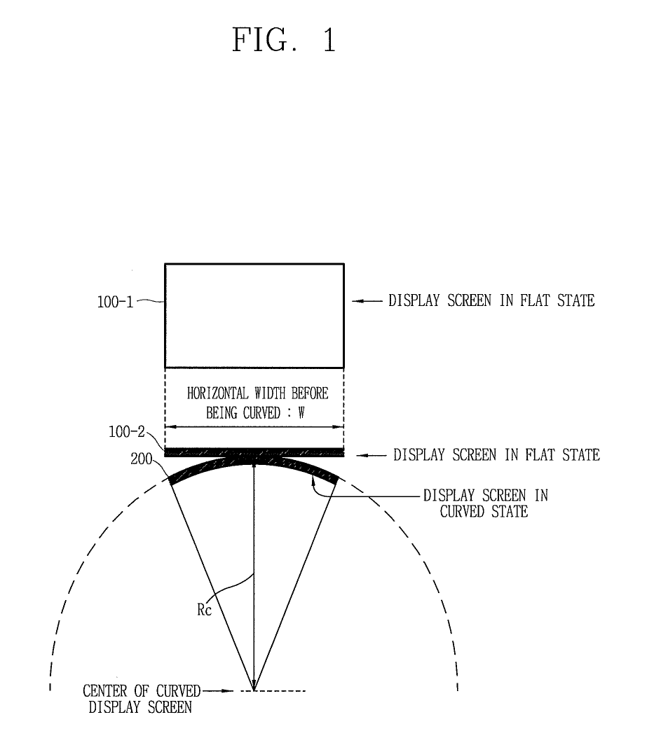

FIG. 1

FIG. 1 illustrates a conceptual view showing a display plane of a display panel curved in a horizontal direction by a predetermined radius of curvature.

Referring to FIG. 1, a conceptual view 100-1 in a horizontal direction with respect to the display panel in a flat state and a conceptual view 100-2 in a vertical direction with respect to the display panel in a flat state are illustrated. Also, a conceptual view 200 in a vertical direction with respect to a curved display panel obtained by curving the flat display panel is illustrated.

The display panel 100 in a flat state may be warped in the horizontal direction to have a predetermined radius of curvature Rc.

The radius of curvature is a value indicating a degree of curving in respective points. As the radius of curvature is great, curving of a curved surface is gentle.

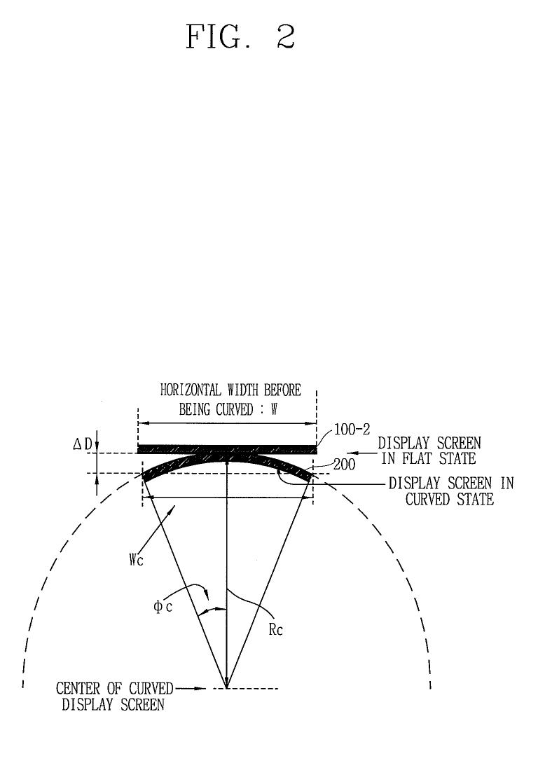

FIG. 2

FIG. 2 illustrates a conceptual view showing information required for determining radius of curvature of curved display.

A device for acquiring a radius of curvature may acquire a horizontal width W of the display panel before the display panel is curved and a radius of curvature Rc of the display panel after the display panel is curved.

Referring to FIG. 2, when the flat display panel 100 is curved to have a predetermined radius of curvature (200), an angle (curvature angle φc) between one end of the horizontal screen from the center of the horizontal display plane and the center of the curving, a horizontal width Wc after the display panel is curved, and a length (ΔD) between the front and the rear of the display plane before and after the display plane is curved may be defined.

Here, the curvature angle (φc) may be expressed by Equation shown below:

$$φ c = \frac{90 \times W}{Π \times Rc} \qquad [ Equation 101 ]$$

Also, the horizontal width (Wc) of the display panel after the display panel may be expressed by Equation shown below.

Wc=2×Rc×sin(φc) [Equation 102]

Also, the distance (ΔD) between the front and the rear of the display panel may be expressed by Equation shown below>

ΔD=Rc×{1−cos(φc)} [Equation 103]

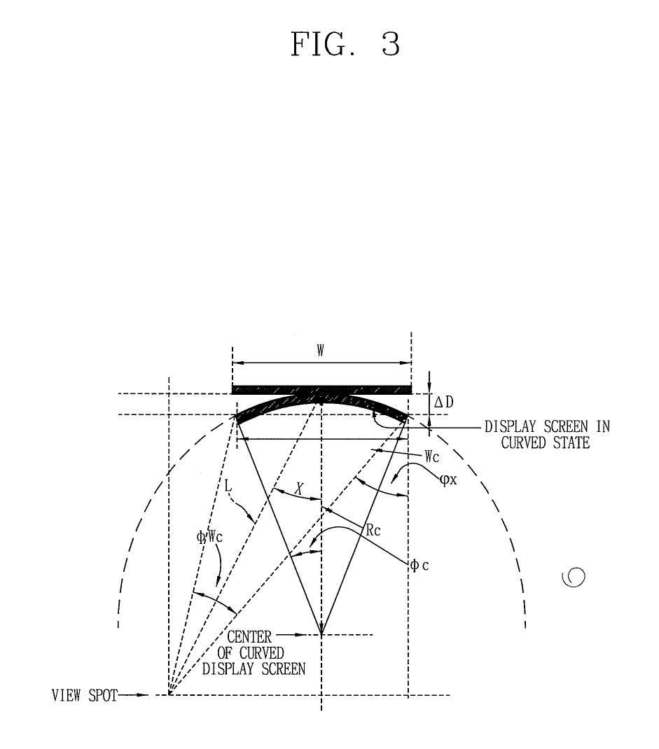

FIG. 3

FIG. 3 illustrates a view showing a viewing angle when a viewer views a curved display panel at an arbitrary spot.

Referring to FIG. 3, it is assumed that a viewer views a display panel in a predetermined view spot (position at which the viewer views the screen).

Here, the view spot is defined as a spot having a predetermined view angle (X) and a predetermined view distance L from the center of the display plane.

Referring to FIG. 3, a horizontal viewing (a viewing angle φWf) of the viewer with respect to the display plane may be checked.

The horizontal viewing (the viewing angle φWf) with respect to the display panel before the display panel is curved may be expressed as follows.

$$φ Wf = {tan}^{- 1} ( \frac{L \times sin ( X ) + \frac{W}{2}}{L \times cos ( X )} ) - {tan}^{- 1} ( \frac{L \times sin ( X ) - \frac{W}{2}}{L \times cos ( X )} ) \qquad [ Equation 104 ]$$

Also, the horizontal viewing (the viewing angle φWf) with respect to the display panel after the display panel is curved may be expressed as follows.

$$φ Wc = {tan}^{- 1} ( \frac{L \times sin ( X ) + \frac{Wc}{2}}{L \times cos ( X ) - Δ D} ) - {tan}^{- 1} ( \frac{L \times sin ( X ) - \frac{Wc}{2}}{L \times cos ( X ) - Δ D} ) \qquad [ Equation 105 ]$$

Here,

Here, L is a view distance, X is a view angle, ΔD is a length between the front and the rear of the display plane before and after the display plane is curved, W is a horizontal width of the display panel before the display panel is curved, and Wc is a horizontal width of the display panel after the display panel is curved.

That is, when the viewing angles of the same display before and after the display is curved are compared, if the view angle when the viewer views the flat display is equal to or greater than 30°, a difference (φWc−φWf) between the horizontal viewing angles may be positive. The difference between the horizontal viewing angles may be defined as a viewing coefficient.

Here, as the value of the viewing coefficient is large, presence of the display can be increased.

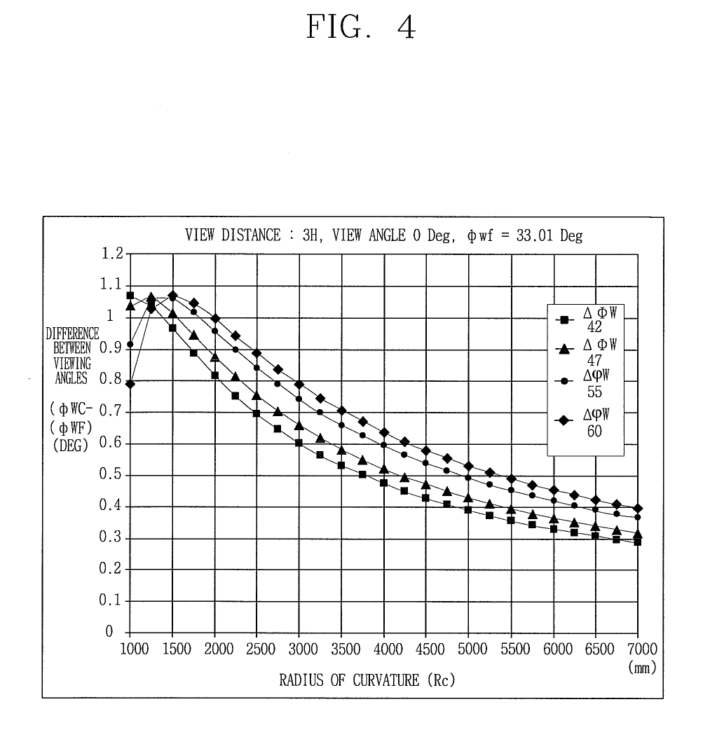

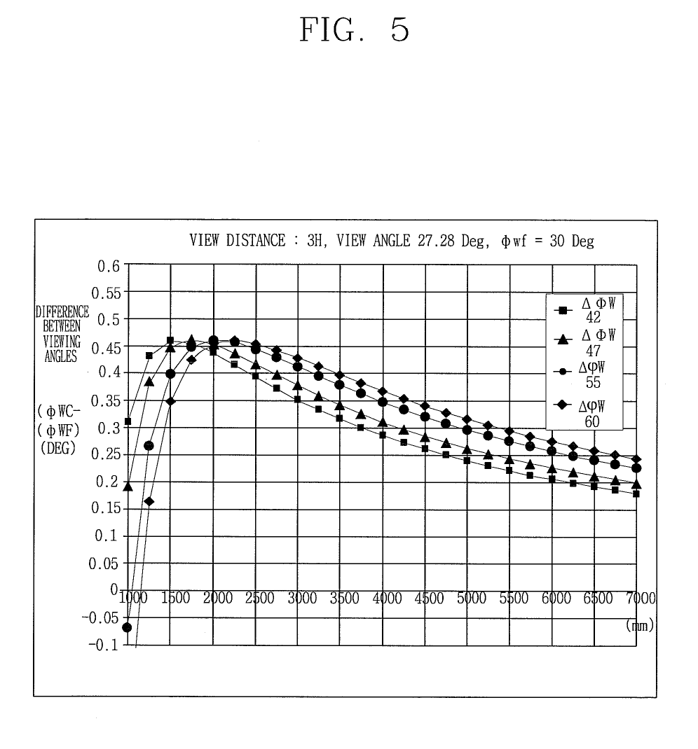

FIGS. 4 and 5

FIGS. 4 and 5 illustrate views showing viewing coefficients with respect to radius of curvature in predetermined view spots with respect to 42-inch, 47-inch, 55-inch, and 60-inch display panels having an aspect ratio of 16:9.

Referring to FIG. 4, the predetermined view spot has a view distance L of 3H (a standard view distance of a high vision display) and a view angle X of 0°. Here, H is a height of the vertical display plane.

Referring to FIG. 5, the predetermined view spot has a view distance L of 3H (a standard view distance of a high vision display) and a view angle X of 27.28°. Here, H is a height of the vertical display plane.

The view angle (X=27.28°) is a value determined based on the fact that presence is increased as the viewing angle is high when the view angle ranges from 30°˜60°. It is a view angle X at which a viewing angle of the flat display is 30° when the view distance L is 3H (L=3H).

Referring to FIGS. 4 and 5, a viewing coefficient with respect to the radius of curvature may be checked.

In particular, in a range in which the radius of curvature is equal to or greater than 2,000 mm, the viewing coefficient (φWc−φWf) increased as the radius of curvature is reduced.

Thus, in order to improve presence, the radius of curvature of the curved display is preferably as small as possible when it is equal to or greater than 2,000 mm.

In general, it has been known that in a range in which a horizontal view angle (an angle of the viewer's eyes with respect to a screen normal) is 30°˜60°, presence is increased as the viewing angle is increased.

Thus, based on the results described above, the horizontal viewing angle (viewing angle) of the viewer with respect to the display plane may be increased, and accordingly, presence can be improved.

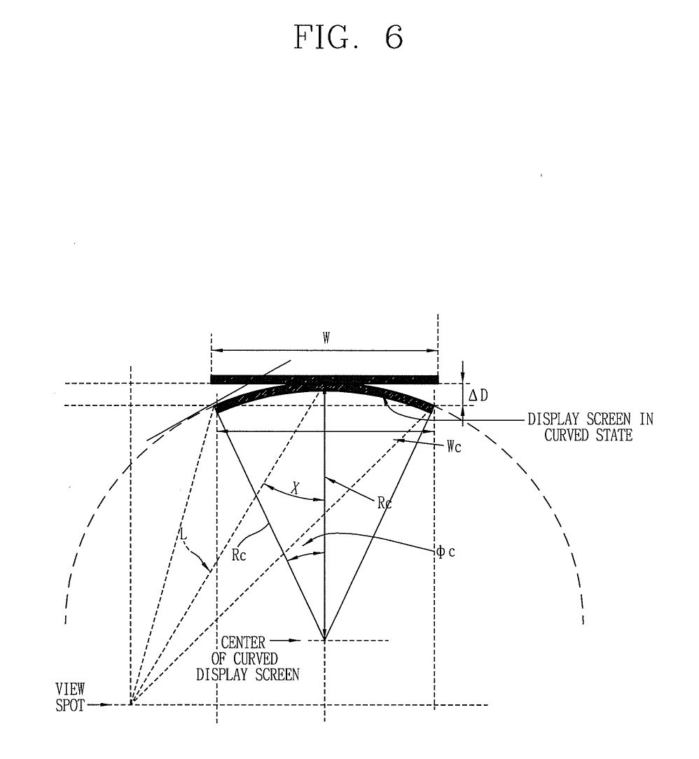

FIG. 6

FIG. 6 illustrates a view showing a panel viewing angle when a viewer views the curved display panel in an arbitrary spot.

Referring to FIG. 6, it is assumed that the viewer views the display panel in a view spot.

Here, the view spot is defined as a spot having a predetermined view angle (X) and a predetermined view distance L from the center of the display plane.

Referring to FIG. 6, a maximum value (φX) of a deviation angle (a panel viewing angle) from a perpendicular of the display plane with respect to the viewer's eyes may be checked.

A maximum value (φXf) of the panel viewing angle with respect to the display panel before the display panel is curved may be expressed as follows.

$$φ Xf = {tan}^{- 1} ( \frac{L \times sin ( X ) + \frac{W}{2}}{L \times cos ( X )} ) \qquad [ Equation 106 ]$$

Also, a maximum value (φXc) of the panel viewing angle with respect to the display panel after the display panel is curved may be expressed as follows.

$$φ Xc = {tan}^{- 1} ( \frac{L \times sin ( X ) - \frac{Wc}{2}}{L \times cos ( X ) - Δ D} ) + φ c \qquad [ Equation 107 ]$$

Here, L is a view distance, X is a view angle, ΔD is a length between the front and the rear of the display plane before and after the display panel is curved, W is a horizontal width of the display panel before the display panel is curved, Wc is a horizontal width of the display panel after the display panel is is curved, and φc is a curvature angle.

That is, when the viewing angles of the same display before and after the display is curved are compared, a difference (φWf−φWc)) between the maximum values of the panel viewing angle may have a positive value. the difference between the maximum values of the panel viewing angle may be defined as a panel viewing coefficient.

Here, as the value of the panel viewing coefficient is higher, a display having uniform characteristics in the entire display plane can be provided.

Meanwhile, preferably, uniformity of the display plane is improved within a normal viewing position range of general households.

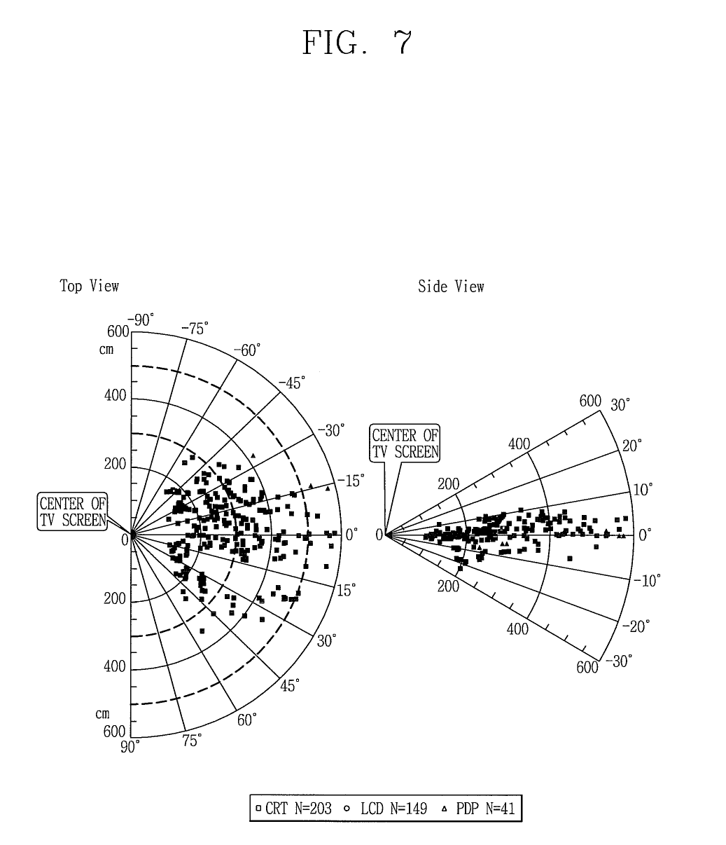

FIG. 7

FIG. 7 illustrates a view showing actual view position situation data with respect to a television receiver reported by Japan Ergonomics Society.

The data was generated by receiving several positions at which family members of respective households generally view a TV, from the family members. The data was obtained from 393 people of 83 households.

FIG. 7(a) is a top view of view positions, and FIG. 7(b) is a side view of view positions.

Referring to FIG. 7, as noted, television viewing conditions were that a view angle was +60 and −60 when a view distance was 3,000 mm, a view angle was +45 and −45 when a view distance was 5,000 mm, and a view angle was +30 and −30 when a view distance was 6,000 mm.

Thus, preferably, uniformity of the display plane is improved within the range as mentioned above.

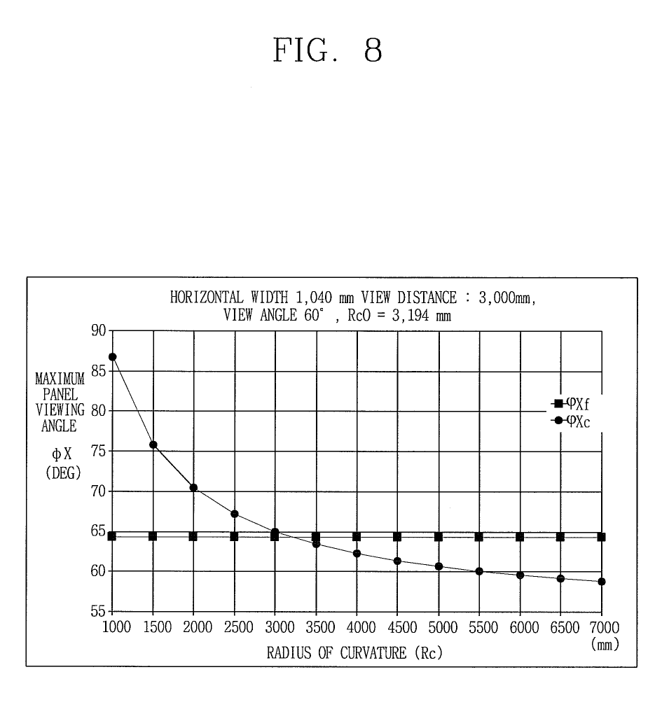

FIGS. 8, 9, and 10

FIGS. 8, 9 and 10 illustrate views showing a maximum value of a panel viewing angle according to radius of curvature according to predetermined conditions with respect to a display having a predetermined horizontal width.

FIG. 8 shows maximum values of the panel viewing angles according to respective radius of curvatures under the conditions of a view distance of 3,000 nm and a view angle of 60° with respect to a display having a horizontal width of 1,040 mm.

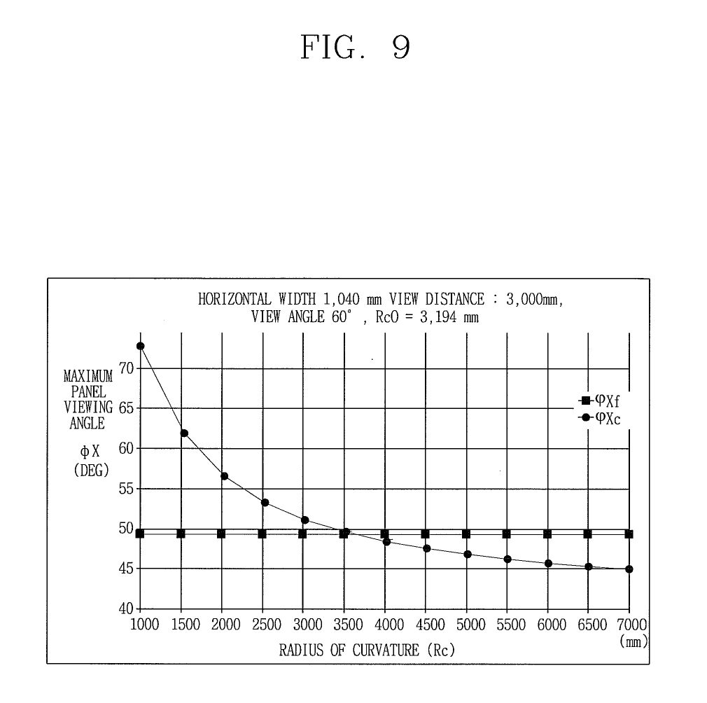

FIG. 9 shows maximum values of the panel viewing angles according to respective radius of curvatures under the conditions of a view distance of 5,000 nm and a view angle of 45° with respect to the display having the horizontal width of 1,040 mm.

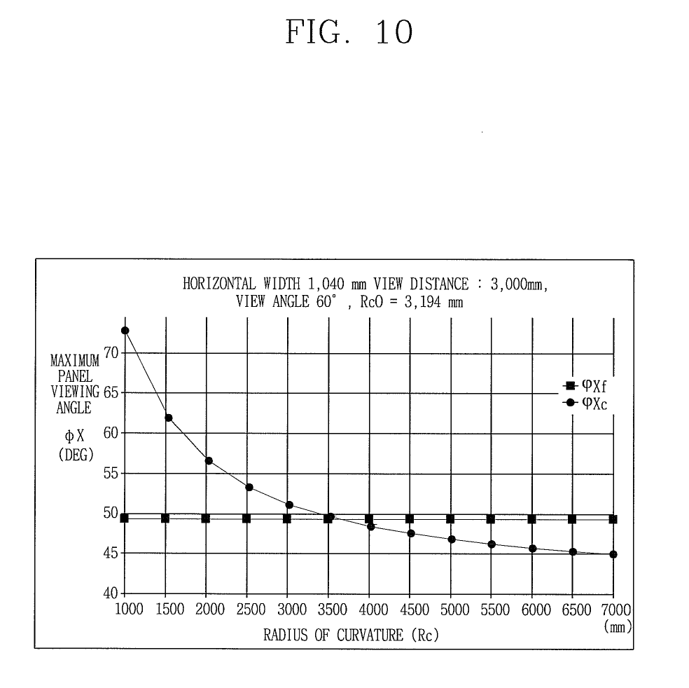

FIG. 10 shows maximum values of the panel viewing angles according to respective radius of curvatures under the conditions of a view distance of 6,000 nm and a view angle of 30° with respect to the display having the horizontal width of 1,040 mm.

Here, φXf is a maximum value of the panel viewing angle with respect to the display panel before the display panel is curved, and φXc is a maximum value of the panel viewing angle with respect to the display panel after the display panel is curved.

Here, through FIGS. 8, 9, and 10, values by which the panel viewing coefficient (φWf−φWc) is positive can be checked.

That is, referring to FIG. 8, in a range in which the radius of curvature Rc is equal to or greater than 3,194 mm, the panel viewing coefficient (φWf−φWc) has a positive value. Referring to FIG. 9, in a range in which the radius of curvature Rc is equal to or greater than 3,659 mm, the panel viewing coefficient (φWf−φWc) has a positive value. Referring to FIG. 10, in a range in which the radius of curvature Rc is equal to or greater than 3,539 mm, the panel viewing coefficient (φWf−φWc) has a positive value.

Through the results, it can be confirmed that it is preferred for a display with a display panel having a horizontal width W of 1,040 mm to have a radius of curvature of 3,659 mm or greater.

The experiment may be conducted on displays having various horizontal widths. Here, experiment results with respect to correlation between a minimum radius curvature required for improving uniformity of a display plane of a curved display and a horizontal width of the display plane are shown in a Table below.

TABLE 1

| | | | | | | | | | | | | | |
|---|---|---|---|---|---|---|---|---|---|---|---|---|---|
| A | 664 | 708 | 819 | 886 | 930 | 1.018 | 1.040 | 1.218 | 1.328 | 1.439 | 1.550 | 1.660 | 1.860 |
| B | 3.616 | 3.621 | 3.634 | 3.641 | 3.646 | 3.656 | 3.659 | 3.678 | 3.690 | 3.701 | 3.713 | 3.724 | 3.744 |

A: Horizontal width W (mm) before curving
B: Minimum radius of curvature Rcmin (mm)

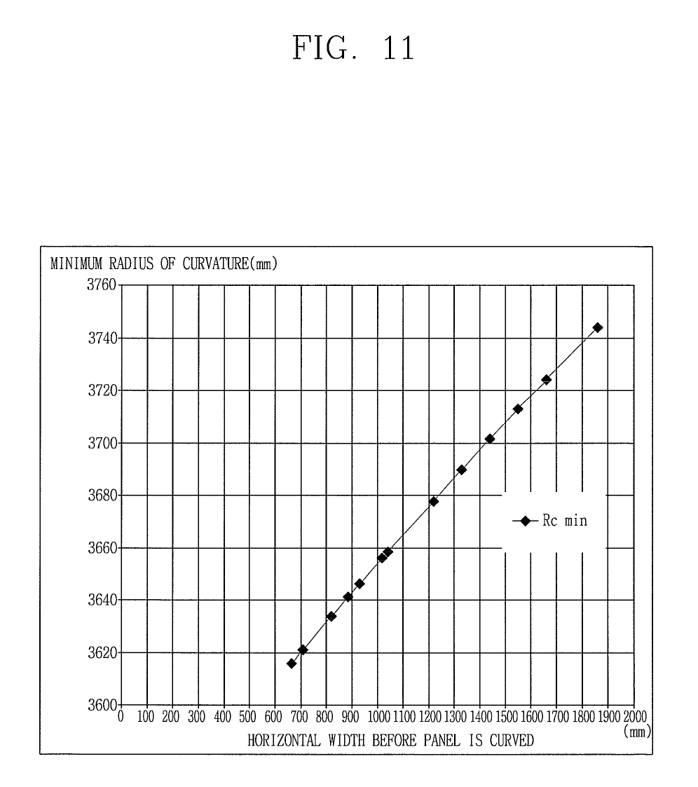

FIG. 11

FIG. 11 illustrates a graph showing correlation between a horizontal width of a display plane and a minimum radius of curvature for improving uniformity of the display plane before a panel is curved.

Referring to FIG. 11, a graph with respect to the correlation may be approximated.

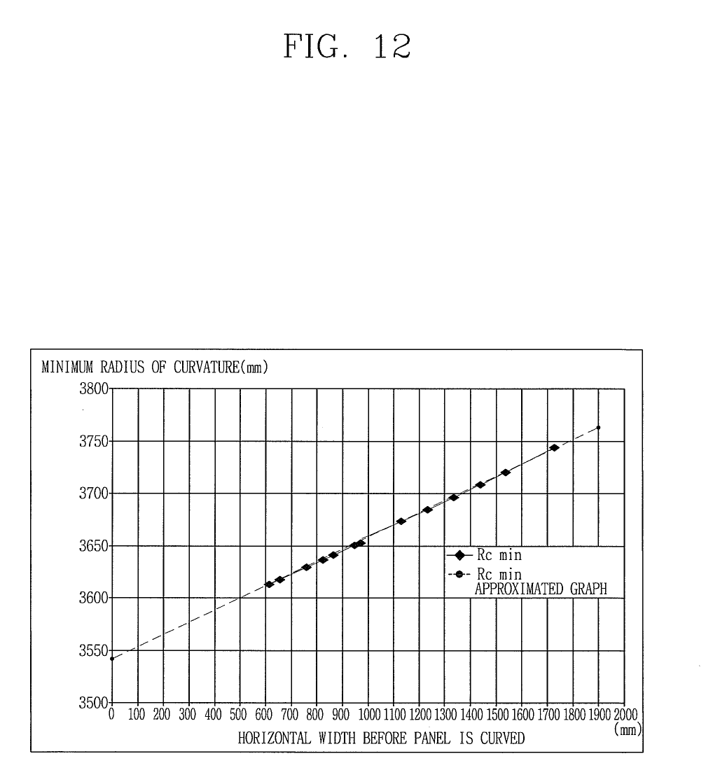

FIG. 12

FIG. 12 illustrates an approximated graph showing correlation between a horizontal width of a display plane and a minimum radius of curvature for improving uniformity of the display plane before a panel is curved.

Referring to FIG. 12, an approximate expression of the correlation between the minimum radius curvature and the horizontal width of the display panel before the display panel is curved may be expressed as follows.

Rcmin′(mm)=0.10927×W(mm)+3545 (mm)

Here, Rcmin′ is the minimum radius of curvature based on the approximate expression, and W is the horizontal width of the display plane before the display panel is curved.

Thus, in order to improve uniformity of the display plane, preferably, the radius of curvature of the curved display panel is set to be equal to or greater than the minimum radius of curvature derived based on Table 1 or Equation 8.

That is, uniformity of the screen according to a panel viewing angle can be improved by using the curved display.

A general display panel has different panel viewing angle characteristics when it is viewed in a vertical direction with respect to the display plane and when viewed in a direction other than the vertical direction. Here, the characteristics are the best when the viewer views the display panel in the vertical direction to the display plane. Also, the characteristics are changed, e.g., luminance or contrast is degraded, when the viewer views the display panel in a direction other than the vertical direction with respect to the display plane.

When the viewer views a flat display, its angle differs according to a view spot and a position within a viewed display plane. Thus, when the viewer views the flat display, the viewer cannot view a display having such characteristics as uniform luminance, contrast, and the like, in the entire display plane.

Here, when the display plane is curved in a horizontal direction, compared with the flat display panel, an angle between the viewer's eyes from a view position (a view spot) of the viewer and the display panel has a difference in portions other than the center of the display panel. That is, in the curved display panel, since both ends of the screen are curved in the direction of the view spot, when the user views the screen in a central spot, a deviation of the panel viewing angle can be reduced.

Based on the qualities and experiment results, a curved display panel providing an image having reduced influence of viewing angle characteristics relying on the panel and high quality uniformity can be provided to users.

The method according to the embodiments of the present disclosure may be individually used or may be combined to be used. Also, steps constituting the respective embodiments may be individually used of may be combined with steps constituting other embodiments and used.

The methods described above may be implemented in a recording medium that may be read by a computer or a similar device by using software, hardware, or a combination thereof.

For hardware implementation, the methods according to embodiments of the present disclosure described herein may be implemented by at least one of application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, and electrical units for performing any other functions.

For software implementation, the procedures and functions according to embodiments of the present disclosure may be implemented in the form of soft modules. The software modules may be implemented by software codes written in an appropriate program language. The software codes may be stored in a storage unit and executed by a processor.

Also, the embodiments of the present invention have been described in detail, but the scope of the present invention is not limited thereto and various variants and modifications by a person skilled in the art using a basic concept of the present invention defined in claims also belong to the scope of the present invention.

The foregoing embodiments and advantages are merely exemplary and are not to be considered as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be considered broadly within its scope as defined in the appended claims, and therefore all changes and modifications that fall within the metes and bounds of the claims, or equivalents of such metes and bounds are therefore intended to be embraced by the appended claims.

What is claimed is:

1. A display device, comprising:
a body; and
a curved display panel mounted at the body,
wherein the curved display panel has a predetermined radius of curvature based on a horizontal width of the display panel and a viewing coefficient based on the horizontal width and the radius of curvature has a positive value,
wherein the viewing coefficient is a value based on a viewing angle of the display panel in a flat state and a viewing angle of the display panel in a curved state.

2. The display device of claim 1, wherein the viewing angle of the display panel in a curved state is expressed by Equation 1 shown below, and
the viewing angle of the display panel in the flat state is expressed by Equation 2 shown below.
$$\begin{matrix}φ Wc = {tan}^{- 1} ( \frac{L \times sin ( X ) + \frac{Wc}{2}}{L \times cos ( X ) - Δ D} ) - {tan}^{- 1} ( \frac{L \times sin ( X ) - \frac{Wc}{2}}{L \times cos ( X ) - Δ D} ) & ( Equation 1 ) \\ φ Wf = {tan}^{- 1} ( \frac{L \times sin ( X ) + \frac{W}{2}}{L \times cos ( X )} ) - {tan}^{- 1} ( \frac{L \times sin ( X ) - \frac{W}{2}}{L \times cos ( X )} ) & ( Equation 2 )\end{matrix}$$
wherein, L is a view distance, X is a view angle, ΔD is a length between the front and the rear of the display plane before and after the display panel is curved, W is a horizontal width of the display panel before the display panel is curved, and Wc is a horizontal width of the display panel after the display panel is curved.

3. The display device of claim 2, wherein the viewing coefficient is expressed by Equation 3 shown below.
φWc−φWf (Equation 3)

4. The display device of claim 2, wherein the view angle (X) has a value ranging from 30° to 60°.

5. The display device of claim 3, wherein the predetermined radius of curvature is a radius of curvature based on at least one of viewing coefficients with respect to a plurality of sets including a plurality of curvatures information.

6. The display device of claim 1, wherein a panel viewing coefficient based on the horizontal width and the radius of curvature has a positive value, and
the panel viewing coefficient is a value based on a panel viewing angle of the display panel in a flat state and a panel viewing angle of the display panel in a curved state.

7. The display device of claim 6, wherein the panel viewing angle of the display panel in a flat state is expressed by Equation 4 shown below, and
the panel viewing angle of the display panel in a curved state is expressed by Equation 5 shown below.
$$\begin{matrix}φ Xf = {tan}^{- 1} ( \frac{L \times sin ( X ) + \frac{W}{2}}{L \times cos ( X )} ) & ( Equation 10 ) \\ φ Xc = {tan}^{- 1} ( \frac{L \times sin ( X ) - \frac{Wc}{2}}{L \times cos ( X ) - Δ D} ) + φ c & ( Equation 11 )\end{matrix}$$
wherein, L is a view distance, X is a view angle, ΔD is a length between the front and the rear of the display plane before and after the display panel is curved, W is a horizontal width of the display panel before the display panel is curved, Wc is a horizontal width of the display panel after the display panel is curved, and φc is a curvature angle.

8. The display device of claim 7, wherein the panel viewing coefficient is expressed by Equation 6 shown below.
φWf−φWc (Equation 6)

9. The display device of claim 7, wherein the predetermined radius of curvature is a radius of curvature based on at least one of panel viewing coefficients with respect to a plurality of sets including a plurality of curvatures information.

10. The display device of claim 1, wherein the radius of curvature has a value equal to or greater than a minimum radius of curvature, and
the minimum radius of curvature is expressed by Equation 7 shown below.
Rcmin′(mm)=0.10927×W(mm)+3545 (mm) (Equation 7)
wherein, Rcmin′ is a minimum radius of curvature, and W is a horizontal width of the display panel before the display panel is curved.

11. The display device of claim 1, wherein the display panel is curved in a horizontal direction.

12. The display device of claim 8, wherein the view distance (L) is 3,000 mm, and the view angle (X) is +60° or −60°.

13. The display device of claim 8, wherein the view distance (L) is 5,000 mm, and the view angle (X) is +45° or −45°.

14. The display device of claim 8, wherein the view distance (L) is 6,000 mm, and the view angle (X) is +30° or −30°.

15. A method for acquiring a radius of curvature of a curved display panel, the method comprising:
obtaining a viewing coefficient based on a viewing angle of the display panel in a flat state and a viewing angle of the display panel in a curved state, at a predetermined spot; and
acquiring a radius of curvature based on the acquired viewing coefficient.

16. The method of claim 15, further comprising:
acquiring a difference between the viewing angle of the display panel in a curved state and the viewing angle of the display panel in a flat state,
wherein the viewing angle of the display panel in a curved state is expressed by Equation 8 shown below and
the viewing angle of the display panel in a flat state is expressed by Equation 9 shown below.
$$\begin{matrix}φ Wc = {tan}^{- 1} ( \frac{L \times sin ( X ) + \frac{Wc}{2}}{L \times cos ( X ) - Δ D} ) - {tan}^{- 1} ( \frac{L \times sin ( X ) - \frac{Wc}{2}}{L \times cos ( X ) - Δ D} ) & ( Equation 8 ) \\ φ Wf = {tan}^{- 1} ( \frac{L \times sin ( X ) + \frac{W}{2}}{L \times cos ( X )} ) - {tan}^{- 1} ( \frac{L \times sin ( X ) - \frac{W}{2}}{L \times cos ( X )} ) & ( Equation 9 )\end{matrix}$$
wherein L is a view distance, X is a view angle, ΔD is a length between the front and the rear of the display plane before and after the display panel is curved, W is a horizontal width of the display panel before the display panel is curved, and Wc is a horizontal width of the display panel after the display panel is curved.

17. The method of claim 15, further comprising:
obtaining a panel viewing coefficient based on a panel viewing angle of the display panel in a flat state and a panel viewing angle of the display panel in a curved state, at a predetermined spot; and
acquiring a radius of curvature based on the acquired panel viewing coefficient.

18. The method of claim 17, wherein the acquiring of the panel viewing coefficient further comprises:
acquiring a difference between the panel viewing angle of the display panel in a flat state and the panel viewing angle of the display panel in a curved state,
wherein the panel viewing angle of the display panel in a flat state is expressed by Equation 10 shown below and
the panel viewing angle of the display panel in a curved state is expressed by Equation 11 shown below.
$$\begin{matrix}φ Xf = {tan}^{- 1} ( \frac{L \times sin ( X ) + \frac{W}{2}}{L \times cos ( X )} ) & ( Equation 10 ) \\ φ Xc = {tan}^{- 1} ( \frac{L \times sin ( X ) - \frac{Wc}{2}}{L \times cos ( X ) - Δ D} ) + φ c & ( Equation 11 )\end{matrix}$$
wherein L is a view distance, X is a view angle, ΔD is a length between the front and the rear of the display plane before and after the display panel is curved, W is a horizontal width of the display panel before the display panel is curved, Wc is a horizontal width of the display panel after the display panel is curved, and φc is a curvature angle.

19. The method of claim 15, wherein the acquiring of the viewing coefficient further comprises:
acquiring a plurality of viewing coefficients with respect to sets including a plurality of curvature information; and
selecting at least one of the plurality of acquired viewing coefficients.

20. The method of claim 17, wherein the radius of curvature has a value equal to or greater than a minimum radius of curvature, and
the minimum radius of curvature is expressed by Equation 12 shown below.
Rcmin′(mm)=0.10927×W(mm)+3545 (mm) (Equation 12)
wherein Rcmin′ is a minimum radius of curvature, and W is a horizontal width of the display panel before the display panel is curved.
